(19) United States
(12) Patent Application Publication
(10) Pub. No.: US 2017/0149015 A1
(43) Pub. Date: May 25, 2017

(54) Manufacturing Method of Anode of Flexible OLED Display Panel and Manufacturing Method of Display Panel

(71) Applicant: EverDisplay Optronics (Shanghai) Limited, Shanghai (CN)

(72) Inventors: Pengtao Kang, Shanghai (CN); Xinye Pan, Shanghai (CN); Jiahao Lu, Shanghai (CN)

(21) Appl. No.: 15/359,991

(22) Filed: Nov. 23, 2016

(30) Foreign Application Priority Data
Nov. 23, 2015 (CN) 201510822116.8

(51) Int. Cl. H01L 51/52; H01L 51/56; H01L 27/32

(52) U.S. Cl. CPC H01L 51/5253; H01L 51/5215; H01L 27/3262; H01L 51/56

(57) ABSTRACT

The present invention relates to a manufacturing method of anode of flexible OLED display panel and a manufacturing method of display panel. The manufacturing method of anode of flexible OLED display panel specifically comprises, depositing a metal tensile covering layer on the surface of the organic self-luminous layer; evaporating or anti-splashing to form a transparent conductive thin-film layer on the surface of the metal tensile covering layer; wherein the transparent conductive thin-film layer and the metal tensile covering layer form the anode of the display panel. When the display panel is in a bended state, the metal tensile covering layer delays the cracking of the transparent conductive thin-film layer inside the display panel and increases the service life of the overall display panel.

The present application claims priority to and the benefit of Chinese Patent Application No. CN 201510822116.8, filed on Nov. 23, 2015, the entire content of which is incorporated herein by reference.

### BACKGROUND OF THE INVENTION

Field of the Invention

The present invention relates to the field of semiconductor display technology, more particularly, to a manufacturing method of an anode of flexible OLED display panel and a manufacturing method of display panel.

Description of the Related Art

OLED (Organic Light-Emitting Diode) has a very excellent display performance, as well as features like self-luminous, simple structure, ultra-thin, fast response, wide viewing angle, low power consumption and can realize flexible display and so on.

The emitting principle of OLED is the carrier injection and recombination leads to light emission phenomenon when the organic semiconductor material and light-emitting material driven by electric field. Specifically, OLED display device usually uses ITO pixel electrode and metal electrode as the anode and cathode of the device, and when driven by a certain voltage, electrons and holes are injected from the cathode and the anode to the electron transport layer and the hole transport layer, and electrons and holes transfer through the electron transport layer and the hole transport layer to the light-emitting layer, and encounter in the light-emitting layer to form excitons and excite luminescent molecules, which emit visible light through radiative relaxation.

Flexible display is the future development trend of various intelligent display screens. One of the key technologies of the manufacturing process of the flexible display screen is the manufacture of the flexible deflectable display panel, the flexible display panel should have features like no cracking when repeatedly bent or folded, corrosion resistance, compatible with process temperature, good water resistance and oxygen ability, and stress of the flexible display panel should be low and will not lead to warp, so that process accuracy of the entire screen display can be ensured, meanwhile the process time of the flexible display panel is also required to not be too long, to avoid increasing the production cost.

As shown in FIG. 1, in the existing OLED display panel, the metal anode layer is usually used to be made of ITO material, the ITO material has a preferable work function (the higher the work function, the better the optical performance), yet the stress of the ITO material itself is large, which is prone to cracking after the flexible display panel experienced multiple bending, and electrical conductivity of the cracking area is low, so during normal use, the cracking area cannot emit light normally, thus it further affects the overall effect of the OLED display panel, and results in the optical performance degradation, and display defect.

### SUMMARY OF THE INVENTION

For the defects of the prior art, the present invention application provides a manufacturing method of an anode of OLED display panel and a manufacturing method of flexible OLED display panel. The present invention application is designed to prevent lower the optical performance degradation of the anode of the OLED display panel from optical performance degradation caused by the bended state of the substrate, and protect normal display of cracking area of the transparent conductive thin-film layer when cracks appears on the transparent conductive thin-film layer of the flexible OLED display panel, so that optic fraction defect rateive can be reduced and the overall visual experience can be enhanced.

To achieve the above-mentioned technical purpose, the technical solution of the present invention is as follows:

A manufacturing method of an anode of OLED display panel, comprising:
forming a metal tensile covering layer on a TFT layer; and
providing a transparent conductive thin-film layer and an organic self-luminous layer on an upper surface of the metal tensile covering layer, wherein the transparent conductive thin-film layer and the metal tensile covering layer form the anode of the OLED display panel.

Preferably, in the above-mentioned manufacturing method of the anode of OLED display panel, ductility of the metal tensile covering layer is higher than that of the transparent conductive thin-film layer.

Preferably, in the above-mentioned manufacturing method of the anode of OLED display panel, a material of the metal tensile covering layer is selected from a group consisting of copper, titanium and gold.

A manufacturing method of a flexible OLED display panel, comprising:

providing a substrate;
providing an insulating layer covering on a surface of the substrate, and then forming a buffer layer on the insulating layer;
providing a TFT layer on the buffer layer;
forming a metal tensile covering layer on the TFT layer; and
depositing a transparent conductive thin-film layer and an organic self-luminous layer on an upper surface of the metal tensile covering layer;
wherein coefficient of thermal expansion of the metal tensile covering layer is substantially the same as coefficient of thermal expansion of the insulating layer.

Preferably, in the above-mentioned manufacturing method of the flexible OLED display panel, a material of the insulating layer is a polyimide thin-film layer, and a thickness of the polyimide thin-film layer is between 10 μm to 20 μm.

Preferably, in the above-mentioned manufacturing method of the flexible OLED display panel, coefficient of thermal expansion of the insulating layer is 15×10⁻⁶ m/° C.

Preferably, in the above-mentioned manufacturing method of the flexible OLED display panel, coefficient of thermal expansion of the substrate is smaller than that of the insulating layer.

Preferably, in the above-mentioned manufacturing method of the flexible OLED display panel, the TFT layer comprises a pixel circuit.

Preferably, in the above-mentioned manufacturing method of the flexible OLED display panel, a material of the metal tensile covering layer is selected from a group consisting of copper, titanium and gold.

Preferably, in the above-mentioned manufacturing method of the flexible OLED display panel, a predetermined thickness of the metal tensile covering layer is between 10 nm to 20 nm.

An OLED display panel, comprising:

a substrate;
an anode layer, comprising a tensile metalmetal tensile covering layer and a transparent conductive thin-film layer; the tensile metalmetal tensile covering layer is formed on the substrate, and the transparent conductive thin-film layer is formed on the tensile metalmetal tensile covering layer;
an organic light-emitting layer, formed on the transparent conductive thin-film layer of the anode layer; and
a cathode layer, formed on the organic light-emitting layer.

Preferably, in the above-mentioned OLED display panel, the substrate comprises at least a buffer layer and a TFT layer formed on the buffer layer.

Preferably, in the above-mentioned OLED display panel, the TFT layer comprises a pixel circuit.

Preferably, in the above-mentioned OLED display panel, ductility of the metal tensile covering layer is higher than that of the transparent conductive thin-film layer.

Preferably, in the above-mentioned OLED display panel, a material of the metal tensile covering layer is selected from a group consisting of copper, titanium and gold, and a thickness thereof is between 10 nm to 20 nm.

Compared with the prior art, the advantages of the present invention are:

The tensile metalmetal tensile metal covering layer of with a predetermined thickness deposited under the transparent conductive thin-film layer, when the OLED display panel is in a bended state, delays the cracking of the transparent conductive thin-film layer inside the OLED display panel and increases the service life of the overall display panel, when the OLED display panel is in a bended state, and when cracks appears on the transparent conductive thin-film layer of the flexible OLED display panel, since the tensile metalmetal tensile covering layer is positioned under the transparent conductive thin-film layer and has good conductivity, the transparent conductive thin-film layer in the cracking area can achieve electric conductivityance by virtue of the tensile metalmetal tensile covering layer, which protects normal display of the cracking area of the transparent conductive thin-film layer and reduces optic fraction defective optic defect rate (display defect), so that the overall visual experience can be enhanced.

### BRIEF DESCRIPTIONS OF THE DRAWINGS

The accompanying drawings, together with the specification, illustrate exemplary embodiments of the present disclosure, and, together with the description, serve to explain the principles of the present invention.

FIG. 1 is a structure diagram of the existing OLED display panel when crack generated;

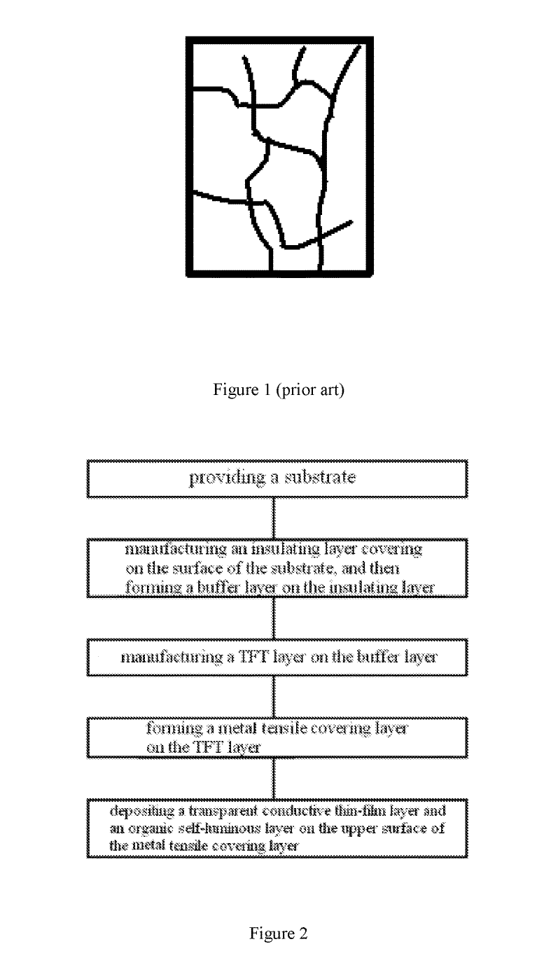

FIG. 2 is a flow diagram of the manufacturing method of a flexible OLED display panel of the present invention;

FIGS. 3a-3d are structure diagrams of an embodiment of an OLED display panel of the present invention;

FIG. 4 is a structure diagram of the organic self-luminous layer of the OLED display panel of the present invention.

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

A manufacturing method of an anode of OLED display panel, comprises:

forming a metal tensile covering layer on a TFT layer; and
providing a transparent conductive thin-film layer and an organic self-luminous layer on the upper surface of the metal tensile covering layer, wherein the aforementioned transparent conductive thin-film layer and the aforementioned metal tensile covering layer form the anode of the OLED display panel.

As a further preferable embodiment, in the above-mentioned manufacturing method of an anode of OLED display panel, the ductility of the metal tensile covering layer is higher than that of the transparent conductive thin-film layer.

As a further preferable embodiment, in the above-mentioned manufacturing method of an anode of OLED display panel, the material of the metal tensile covering layer is selected from a group consisting of copper, titanium and gold.

In the present invention, the metal tensile covering layer is deposited under the transparent conductive thin-film layer, which delays the cracking of the transparent conductive thin-film layer inside the OLED display panel and increases the service life of the overall display panel when the OLED display panel is in a bended state, and protects normal display of the cracking area of the transparent conductive thin-film layer and reduces optic defect rate when crack appears on the transparent conductive thin-film layer of the flexible OLED display panel, so that the overall visual experience can be enhanced.

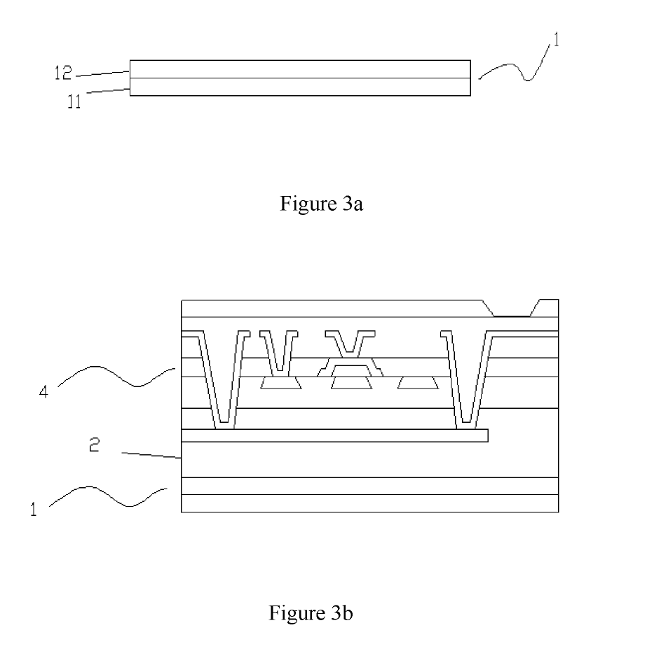

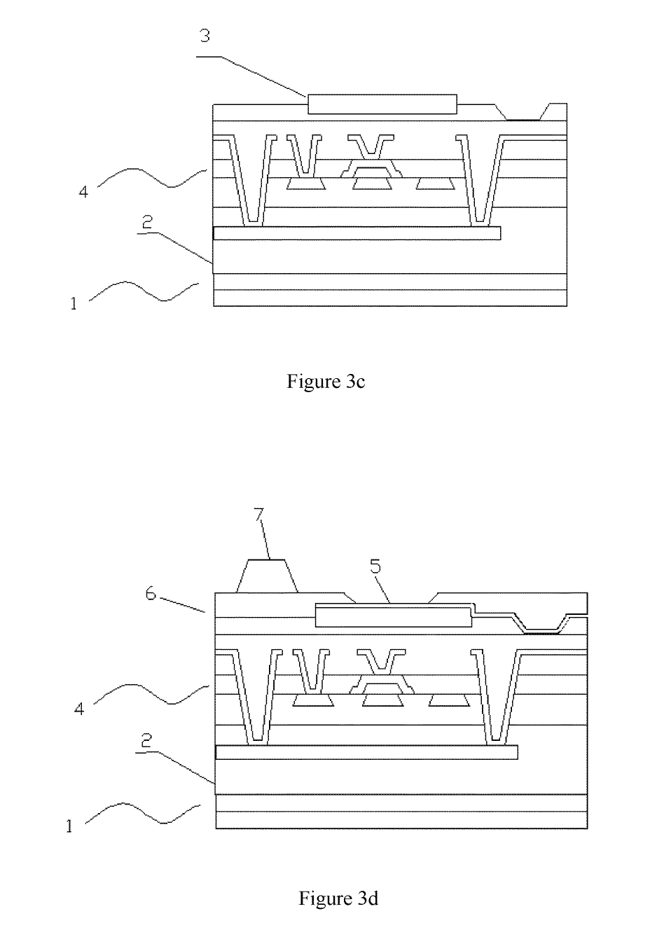

As shown in FIG. 2 and FIGS. 3a-3d, a manufacturing method of flexible OLED display panel comprises:

providing a substrate;
providing an insulating layer 1 covering on the surface of the substrate, and then forming a buffer layer 2 on the insulating layer 1;
providing a TFT layer on the buffer layer 2;
depositing a metal tensile covering layer 3 on the surface of the TFT layer 4; further, the thickness of the metal tensile covering layer 3 is between 10 nm to 20 nm; and
depositing a transparent conductive thin-film layer 5, an organic self-luminous layer, a pixel defining layer 6 and a spacer layer 7 matched with the pixel defining layer 6 on the metal tensile covering layer 3 in turn, so as to complete the OLED display panel; further, the coefficient of thermal expansion of the metal tensile covering layer 3 matches the coefficient of thermal expansion of the insulating layer 1.

The fundamental purpose of the above-mentioned manufacturing method of flexible OLED display panel is: depositing the metal tensile covering layer 3 under the transparent conductive thin-film layer 5 to delay the cracking of the transparent conductive thin-film layer 5 inside the OLED display panel and increase the service life of the overall display panel when the OLED display panel is in a bended state, and when crack appears on the transparent conductive thin-film layer 5 of the flexible OLED display panel; since the metal tensile covering layer 3 is positioned under the transparent conductive thin-film layer 5 and has good conductivity, the transparent conductive thin-film layer 5 in the cracking area can achieve electric conductivity by virtue of the metal tensile covering layer 3, which protects the normal display of the cracking area of the transparent conductive thin-film layer 5 and reduces optic defect rate (display defect), so that the overall visual experience can be enhanced.

Wherein, the coefficient of thermal expansion of the metal tensile covering layer 3 matches the coefficient of thermal expansion of the insulating layer 1 (i.e. the coefficient of thermal expansion of the metal tensile covering layer 3 substantially equals to the coefficient of thermal expansion of the insulating layer 1), in bended state, relative displacement between the metal tensile covering layer 3 and the insulating layer 1 is small, i.e., when the insulating layer 1 is deformed, the metal tensile covering layer 3 will be deformed correspondingly, which releases part of bending stress of the insulating layer 1 so as to greatly reduce the bending stress applied on the transparent conductive thin-film layer 5, and prevent the transparent conductive thin-film layer 5 from generating wrinkling and cracking and protect good electric conductivity thereof.

Further, the insulating layer is a polyimide thin-film layer, and the thickness of the aforementioned polyimide thin-film layer is between 10 μm to 20 μm.

The insulating layer 1 is made of the aforementioned polyimide thin-film layer with a thickness between 10 μm to 20 μm, and the bending strength of the polyimide thin-film layer can reach 345 MPa, the flexural modulus thereof can reach 20 GPa and tensile strength thereof is high, which is used to bend accordingly with the substrate to ensure insulating property of the substrate when it is in a bended state.

As a further preferable embodiment, in the manufacturing method of the OLED display panel, the coefficient of thermal expansion of the insulating layer 1 is matched with matches the coefficient of thermal expansion of the tensile metalmetal tensile covering layer 3. Further, the material of the tensile metalmetal tensile covering layer 3 is selected from a group consisting of copper, titanium and gold. Wherein, the coefficient of thermal expansion of copper is 16.5×10⁻⁶ m/° C., the coefficient of thermal expansion of titanium is 10.8×10⁻⁶ m/° C., the coefficient of thermal expansion of gold is 14.2×10⁻⁶ m/° C., and the coefficient of thermal expansion of the insulating layer 1 is 15×10⁻⁶ m/° C.

As a further preferable embodiment, in the manufacturing method of the OLED display panel, the coefficient of thermal expansion of the substrate is smaller than that of the insulating layer 1. Usually, the substrate having a coefficient of thermal expansion of 5×10⁻⁶ m/° C. is chosen.

As a further preferable embodiment, in the manufacturing method of the aforementioned OLED display panel, the TFT layer 4 comprises the pixel circuit.

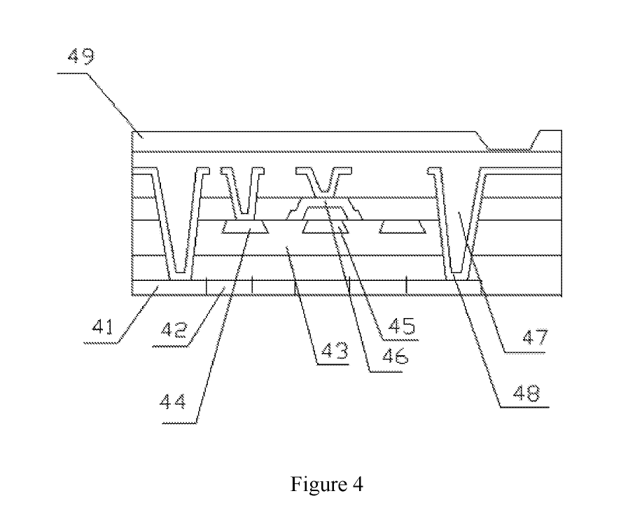

As shown in FIG. 4, the manufacturing process of the organic self-luminous layer is:

forming a heavily doped area 41 and a lightly doped area 42 on the surface of the buffer layer;
depositing a first gate insulating layer (GI1) 43 using chemical vapor deposition method on the surface of the heavily doped area 41 and the lightly doped area 42;
depositing a first gate layer (GL1) 44 using physical vapor deposition method on the surface of the first gate insulating layer (GI1) 43;
depositing a second gate insulating layer (GI2) 45 using chemical vapor deposition method on the surface of the first gate layer (GL1) 44;
depositing a second gate layer (GL2) 46 using physical vapor deposition method on the surface of the second gate insulating layer (GI2) 45;
depositing a interlayer insulating layer (ILD layer) 47 using chemical vapor deposition method on the surface of the second gate layer (GL2) 46;
depositing a data line layer (DL layer) 48 using physical vapor deposition method on the surface of the interlayer insulating layer (ILD layer) 47;
depositing a passivation layer (BP layer) 49 using chemical vapor deposition method on the surface of the data line layer (DL layer) 48; and
exposing the surface of the passivation layer (BP layer) 49 to form a planarizing layer (PL layer).

Wherein, the first gate insulating layer (GI1) 43, the first gate layer (GL1) 44, the second gate insulating layer (GI2) 45, the second gate layer (GL2) 46, the interlayer insulating layer (ILD layer) 47 and the data line layer (DL layer) 48 form the aforementioned TFT (Thin Film Transistor) device. The first gate layer (GL1) 44, the second gate insulating layer (GI2) 45, the second gate layer (GL2) 46, the interlayer insulating layer (ILD layer) 47, the data line layer (DL layer) 48 and the passivation layer (BP layer) 49 form the aforementioned pixel circuit.

As a further preferable embodiment, a transparent conductive thin-film layer, a pixel defining layer and a spacer layer matched with the pixel defining layer on the metal tensile covering layer are deposited in turn to complete the OLED display panel, which specifically comprises:

depositing the aforementioned transparent conductive thin-film layer using physical vapor deposition method on the surface of the aforementioned metal tensile covering layer;
exposing the aforementioned surface of the transparent conductive thin-film layer to form the pixel defining layer; and
exposing the aforementioned surface of the pixel defining layer to form the spacer layer.

The flexible OLED display panel formed by the manufacturing method of flexible OLED display panel comprises the TFT layer 4, the transparent conductive thin-film layer 5 and the metal tensile covering layer configured between the TFT layer 4 and the transparent conductive thin-film layer. When the OLED display panel is in a bended state, the metal tensile covering layer delays the cracking of the transparent conductive thin-film layer 5 inside the OLED display panel and increases the service life of the overall display panel, and protects the normal display of the cracking area of the transparent conductive thin-film layer 5 and reduces optic defect rate when crack appears on the transparent conductive thin-film layer 5 of the flexible OLED display panel, so that the overall visual experience can be enhanced.

The present invention further provides an OLED display panel, comprising:

a substrate; the substrate comprises at least a buffer layer and a TFT layer formed on the buffer layer; further, the TFT layer comprises a pixel circuit;
an anode layer, comprises a metal tensile covering layer and a transparent conductive thin-film layer; the metal tensile covering layer is formed on the substrate, the transparent conductive thin-film layer is formed on the metal tensile covering layer; further, the ductility of the metal tensile covering layer is higher than that of the transparent conductive thin-film layer;
an organic light-emitting layer, formed on the transparent conductive thin-film layer of the anode layer.
a cathode layer, formed on the organic light-emitting layer.

In the above-mentioned OLED display panel, the metal tensile covering layer deposited under the transparent conductive thin-film layer delays the cracking of the transparent conductive thin-film layer inside the OLED display panel and increases the service life of the overall display panel when the OLED display panel is in a bended state, and protects the normal display of the cracking area of the transparent conductive thin-film layer and reduces optic defect rate when crack appears on the transparent conductive thin-film layer of the flexible OLED display panel, so that the overall visual experience can be enhanced.

With regard to the above-mentioned OLED display panel, here further lists an embodiment: as shown in FIGS. 3a-3d and FIG. 4, the structure of an OLED display panel is:

providing a substrate;
forming the insulating layer on the surface of the substrate; further, the insulating layer is a polyimide thin-film layer, and the thickness of the polyimide thin-film layer is between 10 μm to 20 μm;
forming a heavily doped area 41 and a lightly doped area 42 on the surface of the aforementioned buffer layer;
depositing a first gate insulating layer (GI1) 43 on the surface of the aforementioned heavily doped area 41 and the lightly doped area 42;
depositing a first gate layer (GL1) 44 on the surface of the aforementioned first gate insulating layer (GI1) 43;
depositing a second gate insulating layer (GI2) 45 on the surface of the first gate layer (GL1) 44;
depositing a second gate layer (GL2) 46 on the surface of the aforementioned second gate insulating layer (GI2) 45;
depositing a interlayer insulating layer (ILD layer) 47 on the surface of the aforementioned second gate layer (GL2) 46;
depositing a data line layer (DL layer) 48 on the surface of the aforementioned interlayer insulating layer (ILD layer) 47;
depositing a passivation layer (BP layer) 49 on the surface of the aforementioned data line layer (DL layer) 48;
exposing the aforementioned surface of the passivation layer (BP layer) 49 to form a planarizing layer (PL layer);
depositing the aforementioned metal tensile covering layer on the surface of the organic self-luminous layer 4;
depositing the aforementioned transparent conductive thin-film layer on the surface of the metal tensile covering layer;
exposing the aforementioned surface of the transparent conductive thin-film layer to form the pixel defining layer; and
exposing the aforementioned surface of the pixel defining layer to form the spacer layer.

Further, the thickness of the metal tensile covering layer is between 10 nm to 20 nm, and the material thereof is selected from a group consisting of copper, titanium and gold.

In the above-mentioned OLED display panel, the metal tensile covering layer deposited under the transparent conductive thin-film layer delays the crack of the transparent conductive thin-film layer inside the OLED display panel and increases the service life of the overall display panel when the OLED display panel is in a bended state, and protects the normal display of the cracking area of the transparent conductive thin-film layer and reduces optic defect rate when crack appears on the transparent conductive thin-film layer of the flexible OLED display panel, so that the overall visual experience can be enhanced.

The present invention further provides a flexible OLED display device comprising a flexible OLED display panel formed by any one of the above-mentioned manufacturing method of flexible OLED display panel.

A flexible OLED display device comprises the above-mentioned flexible OLED display panel. In the OLED display panel, the metal tensile covering layer with a predetermined thickness deposited under the transparent conductive thin-film layer delays the cracking of the transparent conductive thin-film layer inside the OLED display panel and increases the service life of the overall display panel when the OLED display panel is in a bended state, and when crack appears on the transparent conductive thin-film layer of the flexible OLED display panel, since the metal tensile covering layer is positioned under the transparent conductive thin-film layer and has good conductivity, the transparent conductive thin-film layer in the cracking area can achieve electric conductivity by virtue of the metal tensile covering layer, which protects normal display of the cracking area of the transparent conductive thin-film layer and reduces optic defect rate (display defect), so that overall visual experience can be enhanced.

The operating principle of the flexible OLED display device is similar to the operating principle of the flexible OLED display panel, so it will not be repeated here.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A manufacturing method of an anode of OLED display panel, comprising:
forming a metal tensile covering layer on a TFT layer; and
providing a transparent conductive thin-film layer and an organic self-luminous layer on an upper surface of the metal tensile covering layer;
such that the transparent conductive thin-film layer and the metal tensile covering layer form the anode of the OLED display panel.

2. The manufacturing method of the anode of OLED display panel according to claim 1, wherein ductility of the metal tensile covering layer is higher than that of the transparent conductive thin-film layer.

3. The manufacturing method of the anode of OLED display panel according to claim 1, wherein a material of the metal tensile covering layer is selected from a group consisting of copper, titanium and gold.

4. A manufacturing method of a flexible OLED display panel, comprising:
providing a substrate;
providing an insulating layer covering on a surface of the substrate, and then forming a buffer layer on the insulating layer;
providing a TFT layer on the buffer layer;
forming a metal tensile covering layer on the TFT layer; and
depositing a transparent conductive thin-film layer and an organic self-luminous layer on an upper surface of the metal tensile covering layer;
wherein coefficient of thermal expansion of the metal tensile covering layer is substantially the same as coefficient of thermal expansion of the insulating layer.

5. The manufacturing method of the flexible OLED display panel according to claim 4, wherein a material of the insulating layer is polyimide thin-film, and a thickness of the insulating layer is between 10 μm to 20 μm.

6. The manufacturing method of the flexible OLED display panel according to claim 4, wherein coefficient of thermal expansion of the insulating layer is 15×10⁻⁶ m/° C.

7. The manufacturing method of the flexible OLED display panel according to claim 4, wherein coefficient of thermal expansion of the substrate is smaller than that of the insulating layer.

8. The manufacturing method of the flexible OLED display panel according to claim 4, wherein the TFT layer comprises a pixel circuit.

9. The manufacturing method of the flexible OLED display panel according to claim 4, wherein a material of the metal tensile covering layer is selected from a group consisting of copper, titanium and gold.

10. The manufacturing method of the flexible OLED display panel according to claim 4, wherein a thickness of the metal tensile covering layer is between 10 nm to 20 nm.

11. An OLED display panel, comprising:
a substrate;
an anode layer, comprising a metal tensile covering layer and a transparent conductive thin-film layer; the metal tensile covering layer is formed on the substrate, and the transparent conductive thin-film layer is formed on the metal tensile covering layer;
an organic light-emitting layer, formed on the transparent conductive thin-film layer of the anode layer; and
a cathode layer, formed on the organic light-emitting layer.

12. The OLED display panel according to claim 11, wherein the substrate comprises at least a buffer layer and a TFT layer formed on the buffer layer.

13. The OLED display panel according to claim 12, wherein the TFT layer comprises a pixel circuit.

14. The OLED display panel according to claim 11, wherein ductility of the metal tensile covering layer is higher than that of the transparent conductive thin-film layer.

15. The OLED display panel according to claim 11, wherein a material of the metal tensile covering layer is selected from a group consisting of copper, titanium and gold, and a thickness thereof is between 10 nm to 20 nm.
